(19) United States
(12) Patent Application Publication
(10) Pub. No.: US 2023/0147236 A1
(43) Pub. Date: May 11, 2023

(54) OLED DISPLAY PANEL, MANUFACTURING METHOD THEREOF, AND OLED DISPLAY DEVICE

(71) Applicant: Wuhan China Star Optoelectronics Semiconductor Display Technology Co., Ltd., Wuhan (CN)

(72) Inventor: Jiajia SUN, Wuhan (CN)

(73) Assignee: Wuhan China Star Optoelectronics Semiconductor Display Technology Co., Ltd., Wuhan (CN)

(21) Appl. No.: 16/956,634

(22) PCT Filed: Apr. 9, 2020
(86) PCT No.: PCT/CN2020/083945

§ 371 Date: Jun. 22, 2020

(30) Foreign Application Priority Data
Mar. 25, 2020 (CN) 202010219143.7

(51) Int. Cl. H10K 59/80; H10K 59/124; H10K 59/12

(52) U.S. Cl. CPC H10K 59/873; H10K 59/124; H10K 59/1201; H10K 2102/311

(57) ABSTRACT

An organic light-emitting diode (OLED) display panel, a manufacturing method thereof, and an OLED display device are provided. In the OLED display panel, by disposing a stress buffering member in a concave corner of an undercut section, a stress at the concave corner is eliminated, and the undercut section is prevented from being broken, such that a technical problem that an existing OLED display panel is easily broken from a concave corner of a undercut section, which leads to a failure of the OLED display panel, is solved.

### FIELD OF DISCLOSURE

The present disclosure relates to the field of display technologies, in particular to an organic light-emitting diode (OLED) display panel, a manufacturing method thereof, and an OLED display device.

### BACKGROUND

Organic light-emitting diode (OLED) display devices are widely used in various fields due to their lightness, wide viewing angles, fast response speed, low temperature resistance, high luminous efficiency, and the ability to prepare curved flexible displays. In order to improve a screen-to-body ratio, existing OLED display devices will be designed with special-shaped openings. However, the existing special-shaped openings are set at an edge of a display area, it causes modules (such as under-screen cameras, infrared sensors, earpieces, etc.) to be restricted to the special-shaped openings, and it affects a flexibility of setting the modules (such as under-screen cameras, infrared sensors, earpieces, etc.)

In order to solve the above problems, an existing OLED display panel is designed to be an OLED display panel having an O-cut (O-shaped opening). As shown in FIG. 1, the OLED display panel is designed with an O-shaped through hole in a display area. Due to a flexibility of an installation position of the O-shaped through hole, it is more flexible to set modules (such as under-screen cameras, infrared sensors, earpieces, etc.) under the through hole, which solves the technical problem of inflexible arrangement of the modules (such as under-screen cameras, infrared sensors, earpieces, etc.) In an area of the O-shaped through hole, a plurality of undercut sections are disposed to isolate an organic luminescent material and to prevent water and oxygen from entering. However, during a test of the OLED display panel, it may break from a concave corner of the undercut section, which will cause a failure of the OLED display device.

Accordingly, the existing OLED display panel has a technical problem that it may break from the concave corner of the undercut section, which will cause a failure of the OLED display device.

### SUMMARY OF DISCLOSURE

Embodiments of the present disclosure provide an OLED display panel, a manufacturing method thereof, and an OLED display device to solve a technical problem that an existing OLED display panel is easily broken from a concave corner of an undercut section, which will cause a failure of the OLED display device.

In order to solve the above technical problem, the present disclosure provides technical solutions as follows.

An embodiment of the present disclosure provides an organic light-emitting diode (OLED) display panel, including:
a special-shaped cutting area;
a display area surrounding the special-shaped cutting area. The display area includes an active display area, a first encapsulation area, and a second encapsulation area, and the first encapsulation area and the second encapsulation area are disposed between the active display area and the special-shaped cutting area.

A stress buffering member is disposed in a concave corner of an undercut section of the second encapsulation area.

In some embodiments, the second encapsulation area includes a substrate, a pixel definition layer disposed on the substrate, and an encapsulation layer disposed on the pixel definition layer. In the second encapsulation area, the encapsulation layer includes a first inorganic layer and a second inorganic layer. The OLED display panel includes at least two of the undercut sections, and in the concave corner of at least one of the undercut sections, the stress buffering member is disposed between the first inorganic layer and the second inorganic layer.

In some embodiments, material of the stress buffering member includes an organic material.

In some embodiments, in the first encapsulation area, the encapsulation layer includes the first inorganic layer, the second inorganic layer, and an organic layer disposed between the first inorganic layer and the second inorganic layer. In the second encapsulation area, the stress buffering member is formed by etching the organic layer.

In some embodiments, the OLED display panel further includes a stress buffering layer. In the second encapsulation area, the stress buffering layer is disposed between the first inorganic layer and the second inorganic layer, and the stress buffering member is formed by etching the stress buffering layer.

In some embodiments, the undercut section includes a first concave corner and a second concave corner, the first concave corner is disposed on a left side of the undercut section, the second concave corner is disposed on a right side of the undercut section. In the first concave corner, the stress buffering member is disposed between the first inorganic layer and the second inorganic layer. In the second concave corner, the second inorganic layer is disposed on the first inorganic layer.

In some embodiments, the undercut section includes a first concave corner and a second concave corner, the first concave corner is disposed on a left side of the undercut section, the second concave corner is disposed on a right side of the undercut section. In the first concave corner, the second inorganic layer is disposed on the first inorganic layer. In the second concave corner, the stress buffering member is disposed between the first inorganic layer and the second inorganic layer.

In some embodiments, the undercut section includes a first concave corner and a second concave corner, the first concave corner is disposed on a left side of the undercut section, the second concave corner is disposed on a right side of the undercut section. In the first concave corner and the second concave corner, the stress buffering member is disposed between the first inorganic layer and the second inorganic layer.

In some embodiments, an undercut section is formed in the first encapsulation area, and an organic layer is disposed in the undercut section.

In some embodiments, a first barrier and a second barrier are formed in the first encapsulation area. The first barrier is disposed between the display area and the second barrier.

Also, an embodiment of the present disclosure provides a manufacturing method of an organic light-emitting diode (OLED) display panel, including:
providing a substrate, and etching a second flexible layer and a second barrier layer to form an undercut section, where the substrate includes a first flexible layer, a first barrier layer, the second flexible layer, and the second barrier layer;
forming a thin film transistor array layer on the substrate;
forming a luminous functional layer on the thin film transistor array layer;
forming a first inorganic layer on the luminous functional layer;
forming an organic layer on the first inorganic layer, and etching the organic layer in a second encapsulation area to form a stress buffering member in a concave corner of the undercut section. The OLED display panel includes a special-shaped cutting area and a display area surrounding the special-shaped cutting area, and the display area includes an active display area, a first encapsulation area, and the second encapsulation area, and the first encapsulation area and the second encapsulation area are disposed between the active display area and the special-shaped cutting area; and
forming a second inorganic layer on the first inorganic layer and the organic layer, where an encapsulation layer includes the first inorganic layer, the organic layer, and the second inorganic layer.

Also, an embodiment of the present disclosure provides an organic light-emitting diode (OLED) display device including an OLED display panel. The OLED display panel includes:
a special-shaped cutting area;
a display area surrounding the special-shaped cutting area. The display area includes an active display area, a first encapsulation area, and a second encapsulation area, and the first encapsulation area and the second encapsulation area are disposed between the active display area and the special-shaped cutting area.

A stress buffering member is disposed in a concave corner of an undercut section of the second encapsulation area.

In some embodiments, the second encapsulation area includes a substrate, a pixel definition layer disposed on the substrate, and an encapsulation layer disposed on the pixel definition layer. In the second encapsulation area, the encapsulation layer includes a first inorganic layer and a second inorganic layer. The OLED display panel includes at least two of the undercut sections, and in the concave corner of at least one of the undercut sections, the stress buffering member is disposed between the first inorganic layer and the second inorganic layer.

In some embodiments, material of the stress buffering member includes an organic material.

In some embodiments, in the first encapsulation area, the encapsulation layer includes the first inorganic layer, the second inorganic layer, and an organic layer disposed between the first inorganic layer and the second inorganic layer. In the second encapsulation area, the stress buffering member is formed by etching the organic layer.

In some embodiments, the OLED display panel includes a stress buffering layer. In the second encapsulation area, the stress buffering layer is disposed between the first inorganic layer and the second inorganic layer, and the stress buffering member is formed by etching the stress buffering layer.

In some embodiments, the undercut section includes a first concave corner and a second concave corner, the first concave corner is disposed on a left side of the undercut section, the second concave corner is disposed on a right side of the undercut section. In the first concave corner, the stress buffering member is disposed between the first inorganic layer and the second inorganic layer. In the second concave corner, the second inorganic layer is disposed on the first inorganic layer.

In some embodiments, the undercut section includes a first concave corner and a second concave corner, the first concave corner is disposed on a left side of the undercut section, the second concave corner is disposed on a right side of the undercut section. In the first concave corner, the second inorganic layer is disposed on the first inorganic layer. In the second concave corner, the stress buffering member is disposed between the first inorganic layer and the second inorganic layer.

In some embodiments, the undercut section includes a first concave corner and a second concave corner, the first concave corner is disposed on a left side of the undercut section, the second concave corner is disposed on a right side of the undercut section. In the first concave corner and the second concave corner, the stress buffering member is disposed between the first inorganic layer and the second inorganic layer.

In some embodiments, an undercut section is formed in the first encapsulation area, and an organic layer is disposed in the undercut section.

Embodiments of the present disclosure provide an OLED display panel, a manufacturing method thereof, and an OLED display device. The OLED display panel includes a special-shaped cutting area and a display area. The display area surrounds the special-shaped cutting area. The display area includes an active display area, a first encapsulation area, and a second encapsulation area, and the first encapsulation area and the second encapsulation area are disposed between the active display area and the special-shaped cutting area. A stress buffering member is disposed in a concave corner of an undercut section of the second encapsulation area. By disposing the stress buffering member in the concave corner of the undercut section, a stress at the concave corner is eliminated, and the undercut section is prevented from being broken, such that a technical problem that an existing OLED display panel is easily broken from a concave corner of a undercut section, which leads to a failure of the OLED display panel, is solved.

### BRIEF DESCRIPTION OF DRAWINGS

FIG. 1 is a schematic diagram of an organic light-emitting diode (OLED) display panel in the prior art.

FIG. 2 is a cross-sectional view of the existing OLED display panel of FIG. 1 along A1-A2.

FIG. 3 shows comparison diagrams of the existing OLED display panel before and after a test.

FIG. 4 is a schematic diagram of an OLED display panel of an embodiment of the present disclosure.

FIG. 5 is a first cross-sectional view of the OLED display panel of FIG. 4 along B1-B2.

FIG. 6 is a second cross-sectional view of the OLED display panel of FIG. 4 along B1-B2.

FIG. 7 is a flowchart showing a manufacturing method of an OLED display panel of an embodiment of the present disclosure.

FIG. 8 shows schematic diagrams of the OLED display panel corresponding to processes of the manufacturing method of the OLED display panel.

### DETAILED DESCRIPTION

The present disclosure provides an organic light-emitting diode (OLED) display panel, a manufacturing method thereof, and an OLED display device. In order to more clearly describe the technical solutions of the embodiments of the present disclosure, accompanying drawings to be used in the detailed description of the disclosure will be briefly described hereinbelow. It should be understood that the specific embodiments described herein are only used to explain the present disclosure, and are not used to limit the present disclosure.

The present disclosure embodiment is directed to a technical problem that an existing OLED display panel is easily broken from a concave corner of an undercut section, which will cause a failure of the OLED display device. Embodiments of the present disclosure are employed to solve this technical problem.

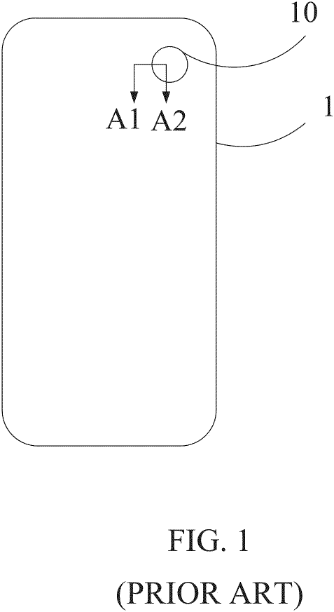

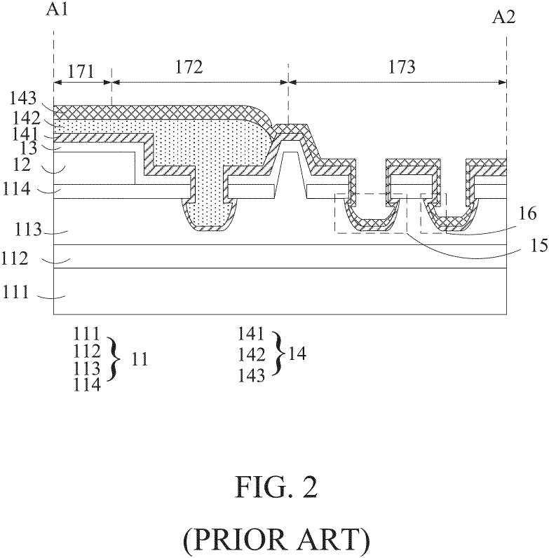

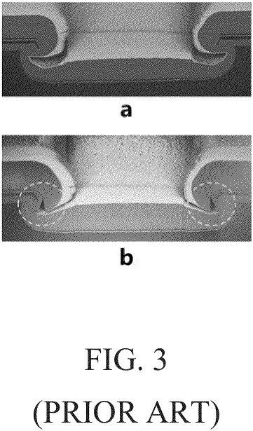

As shown in FIG. 1, in order to achieve flexibility in setting of modules (such as under-screen cameras, infrared sensors, earpieces, etc.), an existing OLED display panel 11 will be provided with an O-shaped opening 10. The O-shaped opening can be set at any position in the display area, such that the setting of the modules (such as under-screen cameras, infrared sensors, earpieces, etc.) is flexible. However, in the OLED display panel, in order to improve an ability of the OLED display panel to prevent water and oxygen from entering, a plurality of undercut sections will be formed in the OLED display panel. As shown in FIG. 2, the OLED display panel includes a substrate 11, a thin film transistor array layer 12, a luminous functional layer 13, and an encapsulation layer 14. The substrate 11 includes a first flexible layer 111, a first inorganic barrier layer 112, a second flexible layer 113, and a second inorganic barrier layer 114. The encapsulation layer 14 includes a first inorganic encapsulation layer 141, a first organic encapsulation layer 142, and a second inorganic encapsulation layer 143. In the OLED display panel, in order to improve the ability of the OLED display panel to prevent water and oxygen from entering, an undercut section 15 will be formed in the OLED display panel. As shown in FIG. 2, the OLED display panel includes an active display area 171, a first encapsulation area 172, and a second encapsulation area 173. The undercut section 15 is disposed in the second encapsulation area 173 to isolate the first organic encapsulation layer 142, thereby preventing the permeation of water and oxygen from the first organic encapsulation layer 142. As shown in a of FIG. 3, during a test of the OLED display panel, there is no damage in the undercut section before the test. However, as shown in b of FIG. 3, after the test of the OLED display panel, a film layer at the concave corner 16 of the undercut section 15 is broken. In actual use, it will cause the OLED display panel to fail, that is, the existing OLED display panel may easily break from the concave corner of the undercut section, resulting in the OLED display panel fails.

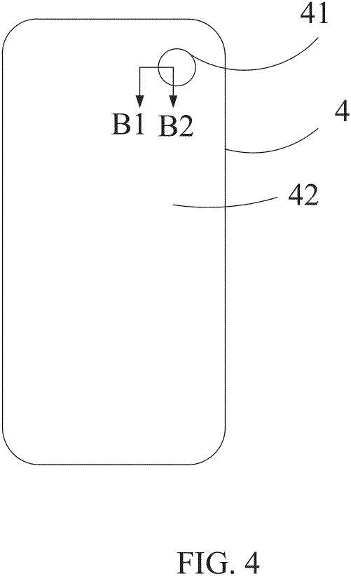

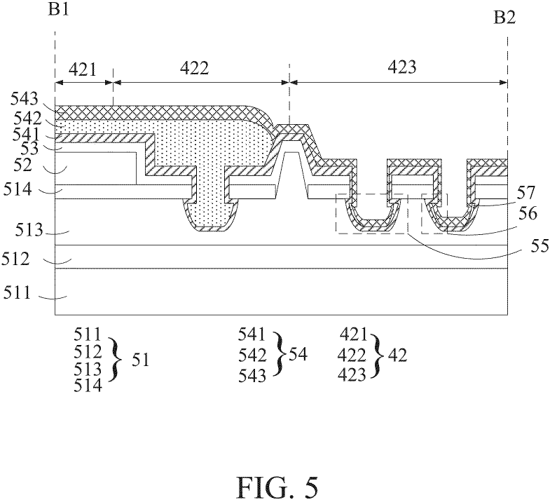

As shown in FIG. 4 and FIG. 5, an embodiment of the present disclosure provides an OLED display panel. The OLED display pane 14 includes a special-shaped cutting area 41 and a display area 42.

The display area 42 surrounds the special-shaped cutting area 41. The display area 42 includes an active display area 421, a first encapsulation area 422, and a second encapsulation area 423, and the first encapsulation area 422 and the second encapsulation area 423 are disposed between the active display area 421 and the special-shaped cutting area 41.

A stress buffering member 57 is disposed in a concave corner 56 of an undercut section 55 of the second encapsulation area 423.

The embodiment of the present disclosure provides the OLED display panel The OLED display panel includes the special-shaped cutting area and the display area. The display area surrounds the special-shaped cutting area. The display area includes the active display area, the first encapsulation area, and the second encapsulation area, and the first encapsulation area and the second encapsulation area are disposed between the active display area and the special-shaped cutting area. The stress buffering member is disposed in the concave corner of the undercut section of the second encapsulation area. By disposing the stress buffering member in the concave corner of the undercut section, a stress at the concave corner is eliminated, and the undercut section is prevented from being broken, such that a technical problem that an existing OLED display panel is easily broken from a concave corner of a undercut section, which leads to a failure of the OLED display panel, is solved.

In one embodiment, as shown in FIG. 5, the OLED display panel includes a substrate 51, a thin film transistor array layer 52, a luminous functional layer 53, and an encapsulation layer 54. The substrate 51 includes a first flexible layer 511, a first barrier layer 512, a second flexible layer 513, and a second barrier layer 514. The thin film transistor array layer 52 includes a buffer layer, an active layer, a first gate insulating layer, a first metal layer, a second gate insulating layer, a second metal layer, an interlayer insulating layer, a source/drain layer, and a planarization layer. The luminous functional layer 53 includes a pixel electrode layer, a pixel definition layer, a light-emitting material layer disposed in a light-emitting area defined by the pixel definition layer, and a common electrode layer. The encapsulation layer 54 includes a first inorganic layer 541, an organic layer 542, and a second inorganic layer 543.

In one embodiment, the second encapsulation area includes a substrate, a pixel definition layer disposed on the substrate, and an encapsulation layer disposed on the pixel definition layer. In the second encapsulation area, the encapsulation layer includes a first inorganic layer and a second inorganic layer. The OLED display panel is formed with at least two of the undercut sections. In the concave corner of at least one undercut section, a stress buffering member is disposed between the first inorganic layer and the second inorganic layer. In the OLED display panel, for film layers in the concave corner of the undercut section in the second encapsulation layer is easily broken, the stress buffering member can be formed in the concave corner of the undercut section. Specifically, the stress buffering member is formed between the first inorganic layer and the second inorganic layer, so that the stress buffering member reduces the stress at the concave corner, thereby preventing the film layers in the concave corner from breaking. Regarding the number of stress buffering member, the stress buffering member can be disposed in a concave corner of one undercut section. Alternatively, the stress buffering members can be disposed in concave corners of a plurality of undercut sections. Alternatively, the stress buffering member can be disposed in a concave corner of each undercut section. Moreover, in the OLED display panel, the undercut sections formed by the encapsulation layer include at least two, so that the organic material layer can be isolated, thereby avoiding water and oxygen from entering, and achieving a better ability to prevent the block water and oxygen.

In one embodiment, material of the stress buffering member includes an organic material. When forming the stress buffering member, considering a high flexibility of the organic material, the organic material can be used as the material of the stress buffering member, such as polystyrene, phenolic resin, etc.

In one embodiment, in the first encapsulation area, the encapsulation layer includes the first inorganic layer, the second inorganic layer, and the organic layer disposed between the first inorganic layer and the second inorganic layer. In the second encapsulation area, the organic layer is etched to form the stress buffering member. In the first encapsulation area and display area, in order to make the display panel have a certain flexibility, the encapsulation layer will be formed by alternately stacking the inorganic layer and the organic layer. The stress buffering member can be formed when the organic layer is etched, thereby reducing the stress at the undercut section.

In one embodiment, the OLED display panel includes a stress buffering layer. In the second encapsulation area, the stress buffering layer is disposed between the first inorganic layer and the second inorganic layer. The stress buffering layer is etched to form the stress buffering member. When forming the stress buffering member, a layer of the stress buffering layer can be formed in the OLED display panel. The stress buffering layer may be made of the organic material, so that the stress buffering layer forms the stress buffering member, and there is no need to change a manufacturing method of the organic layer to reset the stress buffering layer, thereby reducing the stress at the undercut section.

In one embodiment, the undercut section is formed with a first concave corner and a second concave corner. The first concave corner is disposed on a left side of the undercut section. The second concave corner is disposed on a right side of the undercut section. In the first concave corner, the stress buffering member is disposed between the first inorganic layer and the second inorganic layer. In the second concave corner, the second inorganic layer is disposed on the first inorganic layer. There are two concave corners formed in the undercut section. The stress at the first concave corner can be buffered, so as to avoid the first concave corner from breaking due to the stress. In the second concave corner, the first inorganic layer will be directly disposed on the second inorganic layer, and the stress buffering member will not be omitted.

In one embodiment, the undercut section is formed with a first concave corner and a second concave corner. The first concave corner is disposed on a left side of the undercut section. The second concave corner is disposed on a right side of the undercut section. In the first concave corner, the second inorganic layer is disposed on the first inorganic layer. In the second concave corner, the stress buffering member is disposed between the first inorganic layer and the second inorganic layer. When there are two concave corners in the undercut section, the stress at the second concave corner on the right side can be buffered, so as to avoid the stress at the second concave corner being too large, thereby preventing the second concave corner from breaking. Also, the second inorganic layer is directly disposed on the first inorganic layer.

In one embodiment, the undercut section is formed with a first concave corner and a second concave corner. The first concave corner is disposed on a left side of the undercut section. The second concave corner is disposed on a right side of the undercut section. In the first concave corner and the second concave corner, the stress buffering member is provided between the first inorganic layer and the second inorganic layer. When the first concave corner and the second concave corner are formed in the undercut section, by forming the stress buffering member between the first inorganic layer and the second inorganic layer in the first concave corner and the second concave corner, the stress at the first concave corner and the second concave corner is reduced, so that the film layers in the first concave corner and the second concave corner are prevented from breaking, thereby increasing a yield of the OLED display panel.

In one embodiment, the first encapsulation area is formed with the undercut section. The organic layer is provided in the undercut section. In a display panel, the undercut section will be disposed in the first encapsulation area. When the organic layer does not need to be removed in the first encapsulation area, the organic layer can be disposed in the undercut section in the first encapsulation area, so that the stress at the undercut section of the first encapsulation area is low, thereby avoiding breakage, and improving the flexibility of the display panel.

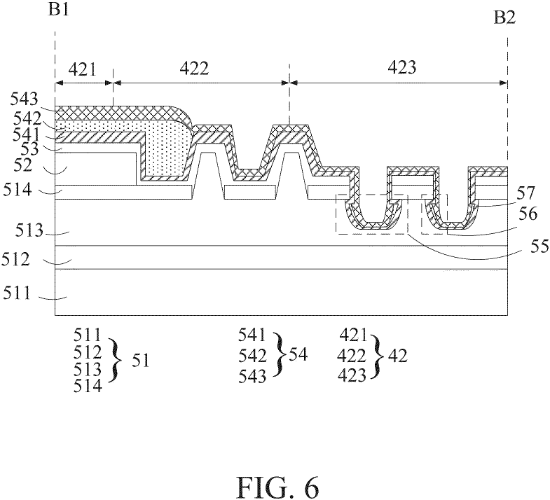

In one embodiment, as shown in FIG. 6, the first encapsulation area is formed with a first barrier and a second barrier. The first barrier is disposed between the display area and the second barrier. When forming the display panel, an undercut section may not form in the first encapsulation area, and the first barrier and the second barrier are form in the first encapsulation area, so that the barriers blocks the organic layer, prevents the organic layer from flowing into the second encapsulation area, and it ensures an encapsulation performance of the encapsulation layer.

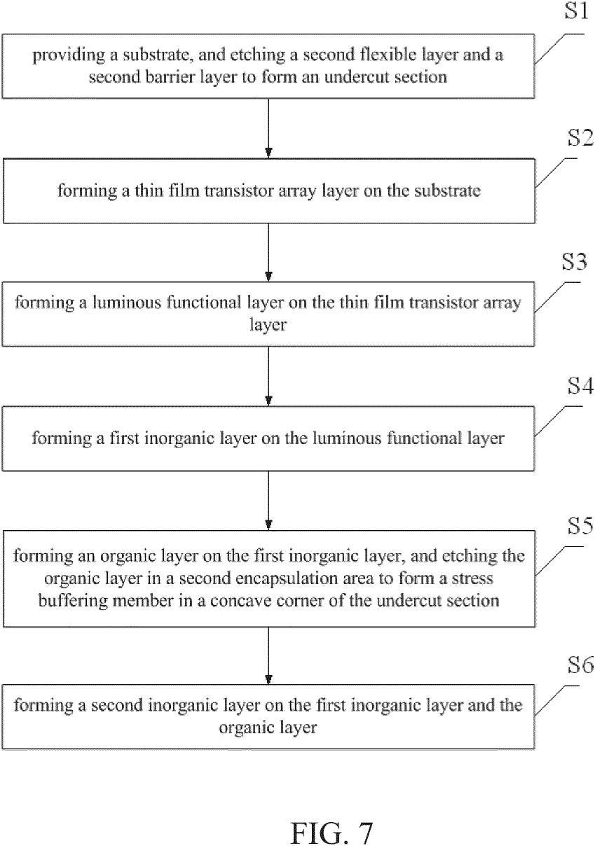

As shown in FIG. 7, an embodiment of the present disclosure provides a manufacturing method of an OLED display panel. The manufacturing method of the OLED display panel includes the following.

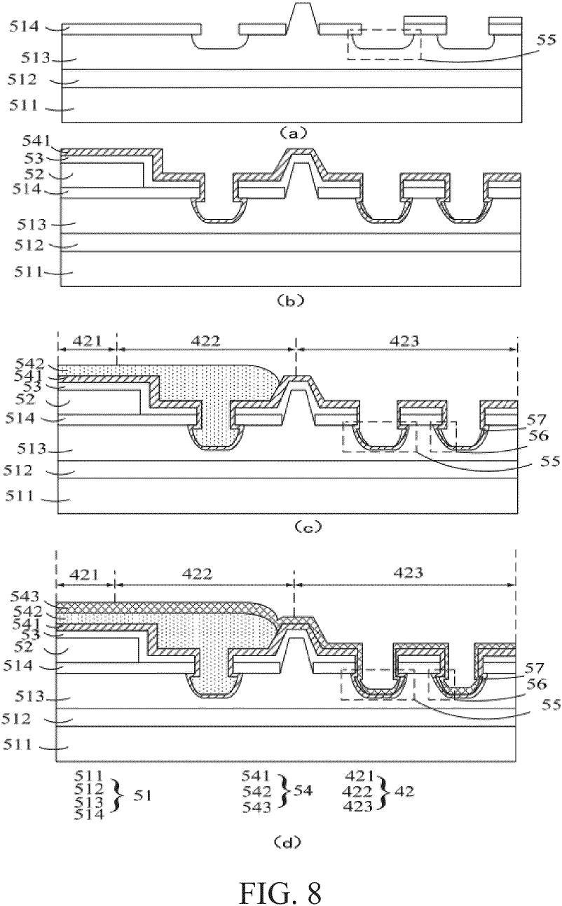

In S1, a substrate is provided, and a second flexible layer and a second barrier layer are etched to form an undercut section. The substrate includes a first flexible layer, a first barrier layer, the second flexible layer, and the second barrier layer, an equivalent diagram is shown in (a) of FIG. 8.

In S2, a thin film transistor array layer is formed on the substrate.

In S3, a luminous functional layer is formed on the thin film transistor array layer.

In S4, a first inorganic layer is formed on the luminous functional layer, an equivalent diagram is shown in (b) of FIG. 8.

In S5, an organic layer is formed on the first inorganic layer, and the organic layer in a second encapsulation area is etched to form a stress buffering member in a concave corner of the undercut section. The OLED display panel includes a special-shaped cutting area and a display area surrounding the special-shaped cutting area. The display area includes an active display area, a first encapsulation area, and the second encapsulation area, and the first encapsulation area and the second encapsulation area are disposed between the active display area and the special-shaped cutting area, an equivalent diagram is shown in (c) of FIG. 8.

In S6, a second inorganic layer is formed on the first inorganic layer and the organic layer. An encapsulation layer includes the first inorganic layer, the organic layer, and the second inorganic layer, an equivalent diagram is shown in (d) of FIG. 8.

The embodiment of the present disclosure provides the manufacturing method of the OLED display panel. The OLED display panel prepared by the manufacturing method of the OLED display panel includes the special-shaped cutting area and the display area. The display area surrounds the special-shaped cutting area. The display area includes the active display area, the first encapsulation area, and the second encapsulation area, and the first encapsulation area and the second encapsulation area are disposed between the active display area and the special-shaped cutting area. The stress buffering member is disposed in the concave corner of the undercut section of the second encapsulation area. By disposing the stress buffering member in the concave corner of the undercut section, a stress at the concave corner is eliminated, and the undercut section is prevented from being broken, such that a technical problem that an existing OLED display panel is easily broken from a concave corner of a undercut section, which leads to a failure of the OLED display panel, is solved.

An embodiment of the present disclosure provides an OLED display device including an OLED display panel. The OLED display panel includes a special-shaped cutting area and a display area.

The display area surrounds the special-shaped cutting area. The display area includes an active display area, a first encapsulation area, and a second encapsulation area, and the first encapsulation area and the second encapsulation area are disposed between the active display area and the special-shaped cutting area.

A stress buffering member is disposed in a concave corner of an undercut section of the second encapsulation area.

In the OLED display device of the embodiment of the present disclosure, the OLED display device includes the OLED display panel. The OLED display panel includes the special-shaped cutting area and the display area. The display area surrounds the special-shaped cutting area. The display area includes the active display area, the first encapsulation area, and the second encapsulation area, and the first encapsulation area and the second encapsulation area are disposed between the active display area and the special-shaped cutting area. The stress buffering member is disposed in the concave corner of the undercut section of the second encapsulation area. By disposing the stress buffering member in the concave corner of the undercut section, a stress at the concave corner is eliminated, and the undercut section is prevented from being broken, such that a technical problem that an existing OLED display panel is easily broken from a concave corner of a undercut section, which leads to a failure of the OLED display panel, is solved.

In one embodiment, in the OLED display device, the second encapsulation area includes a substrate, a pixel definition layer disposed on the substrate, and an encapsulation layer disposed on the pixel definition layer. In the second encapsulation area, the encapsulation layer includes a first inorganic layer and a second inorganic layer. The OLED display panel includes at least two of the undercut sections, and in the concave corner of at least one of the undercut sections, the stress buffering member is disposed between the first inorganic layer and the second inorganic layer.

In one embodiment, in the OLED display device, material of the stress buffering member includes an organic material.

In one embodiment, in the OLED display device, tin the first encapsulation area, the encapsulation layer includes the first inorganic layer, the second inorganic layer, and an organic layer disposed between the first inorganic layer and the second inorganic layer. In the second encapsulation area, the stress buffering member is formed by etching the organic layer.

In one embodiment, in the OLED display device, the OLED display panel includes a stress buffering layer. In the second encapsulation area, the stress buffering layer is disposed between the first inorganic layer and the second inorganic layer, and the stress buffering member is formed by etching the stress buffering layer.

In one embodiment, in the OLED display device, the undercut section includes a first concave corner and a second concave corner, the first concave corner is disposed on a left side of the undercut section, the second concave corner is disposed on a right side of the undercut section. In the first concave corner, the stress buffering member is disposed between the first inorganic layer and the second inorganic layer. In the second concave corner, the second inorganic layer is disposed on the first inorganic layer.

In one embodiment, in the OLED display device, the undercut section includes a first concave corner and a second concave corner, the first concave corner is disposed on a left side of the undercut section, the second concave corner is disposed on a right side of the undercut section. In the first concave corner, the second inorganic layer is disposed on the first inorganic layer. In the second concave corner, the stress buffering member is disposed between the first inorganic layer and the second inorganic layer.

In one embodiment, in the OLED display device, the undercut section includes a first concave corner and a second concave corner, the first concave corner is disposed on a left side of the undercut section, the second concave corner is disposed on a right side of the undercut section. In the first concave corner and the second concave corner, the stress buffering member is disposed between the first inorganic layer and the second inorganic layer.

In one embodiment, in the OLED display device, an undercut section is formed in the first encapsulation area, and an organic layer is disposed in the undercut section.

According to the above embodiments:

The embodiments of the present disclosure provide the OLED display panel, the manufacturing method thereof, and the OLED display device. The OLED display panel includes the special-shaped cutting area and the display area. The display area surrounds the special-shaped cutting area. The display area includes the active display area, the first encapsulation area, and the second encapsulation area, and the first encapsulation area and the second encapsulation area are disposed between the active display area and the special-shaped cutting area. The stress buffering member is disposed in the concave corner of the undercut section of the second encapsulation area. By disposing the stress buffering member in the concave corner of the undercut section, the stress at the concave corner is eliminated, and the undercut section is prevented from being broken, such that a technical problem that an existing OLED display panel is easily broken from a concave corner of a undercut section, which leads to a failure of the OLED display panel, is solved.

It can be understood that, for those of ordinary skill in the art, equivalent replacements or changes can be made according to the technical solutions of the present disclosure and its inventive concept. All these changes or replacements shall fall within the protection scope of the claims attached to the present disclosure.

What is claimed is:

1. An organic light-emitting diode (OLED) display panel, comprising:
a special-shaped cutting area; and
a display area surrounding the special-shaped cutting area, wherein the display area comprises an active display area, a first encapsulation area, and a second encapsulation area, and the first encapsulation area and the second encapsulation area are disposed between the active display area and the special-shaped cutting area;
wherein a stress buffering member is disposed in a concave corner of an undercut section of the second encapsulation area.

2. The OLED display panel as claimed in claim 1, wherein the second encapsulation area comprises a substrate, a pixel definition layer disposed on the substrate, and an encapsulation layer disposed on the pixel definition layer;
in the second encapsulation area, the encapsulation layer comprises a first inorganic layer and a second inorganic layer; and
the OLED display panel comprises at least two of the undercut sections, and in the concave corner of at least one of the undercut sections, the stress buffering member is disposed between the first inorganic layer and the second inorganic layer.

3. The OLED display panel as claimed in claim 2, wherein material of the stress buffering member comprises an organic material.

4. The OLED display panel as claimed in claim 2, wherein in the first encapsulation area, the encapsulation layer comprises the first inorganic layer, the second inorganic layer, and an organic layer disposed between the first inorganic layer and the second inorganic layer, and wherein in the second encapsulation area, the stress buffering member is formed by etching the organic layer.

5. The OLED display panel as claimed in claim 2, further comprising a stress buffering layer, wherein in the second encapsulation area, the stress buffering layer is disposed between the first inorganic layer and the second inorganic layer, and the stress buffering member is formed by etching the stress buffering layer.

6. The OLED display panel as claimed in claim 2, wherein the undercut section comprises a first concave corner and a second concave corner, the first concave corner is disposed on a left side of the undercut section, the second concave corner is disposed on a right side of the undercut section, wherein in the first concave corner, the stress buffering member is disposed between the first inorganic layer and the second inorganic layer, and wherein in the second concave corner, the second inorganic layer is disposed on the first inorganic layer.

7. The OLED display panel as claimed in claim 2, wherein the undercut section comprises a first concave corner and a second concave corner, the first concave corner is disposed on a left side of the undercut section, the second concave corner is disposed on a right side of the undercut section, wherein in the first concave corner, the second inorganic layer is disposed on the first inorganic layer, and wherein in the second concave corner, the stress buffering member is disposed between the first inorganic layer and the second inorganic layer.

8. The OLED display panel as claimed in claim 2, wherein the undercut section comprises a first concave corner and a second concave corner, the first concave corner is disposed on a left side of the undercut section, the second concave corner is disposed on a right side of the undercut section, and wherein in the first concave corner and the second concave corner, the stress buffering member is disposed between the first inorganic layer and the second inorganic layer.

9. The OLED display panel as claimed in claim 2, wherein an undercut section is formed in the first encapsulation area, and an organic layer is disposed in the undercut section.

10. The OLED display panel as claimed in claim 1, further comprising a first barrier and a second barrier formed in the first encapsulation area, wherein the first barrier is disposed between the display area and the second barrier.

11. A manufacturing method of an organic light-emitting diode (OLED) display panel, comprising:
providing a substrate, and etching a second flexible layer and a second barrier layer to form an undercut section, wherein the substrate comprises a first flexible layer, a first barrier layer, the second flexible layer, and the second barrier layer;
forming a thin film transistor array layer on the substrate;
forming a luminous functional layer on the thin film transistor array layer;
forming a first inorganic layer on the luminous functional layer;
forming an organic layer on the first inorganic layer, and etching the organic layer in a second encapsulation area to form a stress buffering member in a concave corner of the undercut section, wherein the OLED display panel comprises a special-shaped cutting area and a display area surrounding the special-shaped cutting area, and the display area comprises an active display area, a first encapsulation area, and the second encapsulation area, and the first encapsulation area and the second encapsulation area are disposed between the active display area and the special-shaped cutting area; and
forming a second inorganic layer on the first inorganic layer and the organic layer, wherein an encapsulation layer comprises the first inorganic layer, the organic layer, and the second inorganic layer.

12. An organic light-emitting diode (OLED) display device, comprising an OLED display panel, wherein the OLED display panel comprises:
a special-shaped cutting area;
a display area surrounding the special-shaped cutting area, wherein the display area comprises an active display area, a first encapsulation area, and a second encapsulation area, and the first encapsulation area and the second encapsulation area are disposed between the active display area and the special-shaped cutting area;
wherein a stress buffering member is disposed in a concave corner of an undercut section of the second encapsulation area.

13. The OLED display device as claimed in claim 12, wherein the second encapsulation area comprises a substrate, a pixel definition layer disposed on the substrate, and an encapsulation layer disposed on the pixel definition layer;
in the second encapsulation area, the encapsulation layer comprises a first inorganic layer and a second inorganic layer;
the OLED display panel comprises at least two of the undercut sections, and in the concave corner of at least one of the undercut sections, the stress buffering member is disposed between the first inorganic layer and the second inorganic layer.

14. The OLED display device as claimed in claim 13, wherein material of the stress buffering member comprises an organic material.

15. The OLED display device as claimed in claim 13, wherein in the first encapsulation area, the encapsulation layer comprises the first inorganic layer, the second inorganic layer, and an organic layer disposed between the first inorganic layer and the second inorganic layer, and wherein in the second encapsulation area, the stress buffering member is formed by etching the organic layer.

16. The OLED display device as claimed in claim 13, wherein the OLED display panel comprises a stress buffering layer, wherein in the second encapsulation area, the stress buffering layer is disposed between the first inorganic layer and the second inorganic layer, and the stress buffering member is formed by etching the stress buffering layer.

17. The OLED display device as claimed in claim 13, wherein the undercut section comprises a first concave corner and a second concave corner, the first concave corner is disposed on a left side of the undercut section, the second concave corner is disposed on a right side of the undercut section, wherein in the first concave corner, the stress buffering member is disposed between the first inorganic layer and the second inorganic layer, and wherein in the second concave corner, the second inorganic layer is disposed on the first inorganic layer.

18. The OLED display device as claimed in claim 13, wherein the undercut section comprises a first concave corner and a second concave corner, the first concave corner is disposed on a left side of the undercut section, the second concave corner is disposed on a right side of the undercut section, wherein in the first concave corner, the second inorganic layer is disposed on the first inorganic layer, and wherein in the second concave corner, the stress buffering member is disposed between the first inorganic layer and the second inorganic layer.

19. The OLED display device as claimed in claim 13, wherein the undercut section comprises a first concave corner and a second concave corner, the first concave corner is disposed on a left side of the undercut section, the second concave corner is disposed on a right side of the undercut section, and wherein in the first concave corner and the second concave corner, the stress buffering member is disposed between the first inorganic layer and the second inorganic layer.

20. The OLED display device as claimed in claim 13, wherein an undercut section is formed in the first encapsulation area, and an organic layer is disposed in the undercut section.
